(19) United States
(12) Patent Application Publication
(10) Pub. No.: US 2026/0271658 A1
(43) Pub. Date: Sep. 10, 2026

(54) SYSTEMS AND METHODS FOR WAFER TEMPERATURE MEASUREMENT

(71) Applicant: Lam Research Corporation, Fremont, CA (US)

(72) Inventors: Songqi Gao, San Jose, CA (US); Tianxing Man, Union City, CA (US); Devin Scheifele, San Jose, CA (US)

(21) Appl. No.: 18/876,535

(22) PCT Filed: Jun. 28, 2023
(86) PCT No.: PCT/US2023/026409

§ 371 Date: Dec. 18, 2024

Related U.S. Application Data
(60) Provisional application No. 63/367,519, filed on Jul. 1, 2022.

(51) Int. Cl. H10P 72/00; G01K 3/06; G01K 7/02; G01K 15/00

(52) U.S. Cl. CPC H10P 72/0602; G01K 3/06; G01K 7/028; G01K 15/005

(57) ABSTRACT

Various embodiments herein relate to apparatuses and methods for measuring wafer temperature. In some embodiments, an apparatus comprises a first thermocouple disposed in or on a wafer support, a first conductive pad with a first side and a second side, and a second conductive pad with a first side and a second side. In some embodiments, the first thermocouple is operatively connected to the second side of the second conductive pad, the second side of the first conductive pad is adhered to the first side of the second conductive pad, the first side of the first conductive pad is configured to be proximate to a wafer, and the first thermocouple is configured to indicate an absolute temperature of the wafer.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

Semiconductor fabrication often involves patterning schemes and other processes whereby some materials are selectively etched to prevent etching of other exposed surfaces of a substrate. As device geometries become smaller and smaller, high etch selectivity processes are desirable to achieve effective etching of desired materials without plasma assistance. High etch selectivity processes may depend on accurate wafer temperature measurement. However, such accurate wafer temperature measurements may be difficult to achieve.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are apparatuses, systems, and methods for wafer temperature measurement.

In some embodiments, an apparatus is provided. The apparatus may comprise: a first thermocouple disposed in or on a wafer support; a first conductive pad with a first side and a second side; and a second conductive pad with a first side and a second side. In some embodiments, the first thermocouple is operatively connected to the second side of the second conductive pad, the second side of the first conductive pad is adhered to the first side of the second conductive pad, the first side of the first conductive pad is configured to be proximate to a wafer, and the first thermocouple is configured to indicate an absolute temperature of the wafer.

In some examples, the apparatus further comprises a second thermocouple. In some examples, the second thermocouple is disposed such that an end of the second thermocouple is configured to be further from the wafer than an end of the second thermocouple, and wherein the second thermocouple is disposed in or on the wafer support.

In some examples, the apparatus further comprises a ball and socket joint, wherein the second side of the second conductive pad is in contact with a ball of the ball and socket joint. In some examples, the second conductive pad is configured to tilt up to about +/−2 degrees.

In some examples, the second conductive pad is comprised of nickel.

In some examples, the second conductive pad has a thickness within a range of about 0.002 inches to 0.006 inches.

In some examples, the first conductive pad comprises aluminum nitride.

In some examples, the first conductive pad has a thickness of about 0.05 inches or less.

In some examples, a wire of the first thermocouple is welded to the second side of the second conductive pad.

In some examples, the second side of the first conductive pad is adhered to the first side of the second conductive pad by a thermal gasket adhesive. In some examples, the thermal gasket adhesive is about 0.0025 inches thick or less.

In some examples, the absolute temperature of the wafer is provided without backside gas injection.

In some embodiments, an apparatus for semiconductor processing is provided. The apparatus may comprise: an airlock; and a temperature probe. The temperature probe may be integrated into a wafer support located within the airlock. The wafer support may be configured to support a wafer. The temperature probe may be configured to provide an absolute temperature of the wafer.

In some examples, the apparatus further comprises a controller configured to utilize the absolute temperature in connection with readings from one or more other temperature probes disposed in a process station of the apparatus.

In some examples, the temperature probe comprises: a first thermocouple; a first conductive pad with a first side and a second side; and a second conductive pad with a first side and a second side. In some embodiments, the first thermocouple is operatively connected to the second side of the second conductive pad, and the second side of the first conductive pad is adhered to the first side of the second conductive pad.

In some embodiments, a method of determining wafer temperatures is provided. The method may comprise: determining an environmental temperature of an airlock using a first thermocouple disposed in a wafer support during an idle state of the airlock; obtaining temperature readings from the first thermocouple and a second thermocouple, wherein the second thermocouple is configured to measure a wafer temperature of a wafer proximate to a conductive pad operatively connected to the second thermocouple; and determining an absolute temperature of the wafer based at least in part on a combination of the environmental temperature of the airlock, the temperature readings from the first thermocouple, and the temperature readings from the second thermocouple.

In some examples, the combination comprises a combination of: i) a difference between the temperature readings from the first thermocouple and the environmental temperature of the airlock;

and ii) a difference between the temperature readings from the second thermocouple and the environmental temperature of the airlock. In some examples, the combination of i) and ii) is a weighted sum using weights determined during a calibration procedure.

### BRIEF DESCRIPTION OF THE DRAWINGS

FIG. 1A depicts a cross-sectional side view of an example apparatus in accordance with disclosed embodiments.

FIGS. 1B and 1C depict the pedestal of FIG. 1A with additional features in accordance with various embodiments.

FIG. 1D depicts a substrate support of FIGS. 1A and 1B in accordance with disclosed embodiments.

FIG. 2 is a schematic diagram of a top view of an example load lock in accordance with disclose embodiments.

FIG. 3 is a cross-sectional side view of an example wafer support with an integrated temperature probe in accordance with some embodiments.

FIG. 4 is a side view of an example wafer support with an integrated temperature probe in accordance with some embodiments.

FIG. 5 is a schematic diagram of a top view of an example wafer support with an integrated temperature probe in accordance with some embodiments.

FIG. 6 is a flowchart of an example process for determining an absolute wafer temperature in accordance with some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often involve patterning and etching of various materials, including conductors, semiconductors, and dielectrics. Some examples include conductors, such as metals or carbon; semiconductors, such as silicon or germanium; and dielectrics, such as silicon oxide, aluminum dioxide, zirconium dioxide, hafnium dioxide, silicon nitride, and titanium nitride. Atomic layer etching (“ALE”) processes provide one class of etching techniques that involve repeated variations in etch conditions over the course of an etch operation. ALE processes remove thin layers of material using sequential self-limiting reactions. Generally, an ALE cycle is the minimum set of operations used to perform an etch process one time, such as etching a monolayer. The result of one ALE cycle is that at least some of a film layer on a substrate surface is etched. Typically, an ALE cycle includes a modification operation to form a reactive layer, followed by a removal operation to remove or etch only this reactive layer. The cycle may include certain ancillary operations such as removing one of the reactants or byproducts. Generally, a cycle contains one instance of a unique sequence of operations.

As an example, a conventional ALE cycle may include the following operations: (i) delivery of a reactant gas to perform a modification operation, (ii) purging of the reactant gas from the chamber, (iii) delivery of a removal gas and an optional plasma to perform a removal operation, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process; the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate, and can be supplied into the process chamber housing the substrate.

In some instances, a purge may be performed after a modification operation. In a purge operation, non-surface-bound active chlorine species may be removed from the process chamber. This can be done by purging and/or evacuating the process chamber to remove the active species, without removing the adsorbed layer. The species generated in a chlorine plasma can be removed by simply stopping the plasma and allowing the remaining species decay, optionally combined with purging and/or evacuation of the chamber. Purging can be done using any inert gas such as N2, Ar, Ne, He and their combinations.

In a removal operation, the substrate may be exposed to an energy source to etch the substrate by directional sputtering (this may include activating or sputtering gas or chemically reactive species that induce removal). In some embodiments, the removal operation may be performed by ion bombardment using argon or helium ions. During removal, a bias may be optionally turned on to facilitate directional sputtering. In some embodiments, ALE may be isotropic; in some other embodiments ALE is not isotropic when ions are used in the removal process.

In various examples, the modification and removal operations may be repeated in cycles, such as about 1 to about 30 cycles, or about 1 to about 20 cycles. Any suitable number of ALE cycles may be included to etch a desired amount of film. In some embodiments, ALE is performed in cycles to etch about 1 Å to about 50 Å of the surface of the layers on the substrate. In some embodiments, cycles of ALE etch between about 2 Å and about 50 Å of the surface of the layers on the substrate. In some embodiments, each ALE cycle may etch at least about 0.1 Å, 0.5 Å, or 1 Å.

In some instances, prior to etching, the substrate may include a blanket layer of material, such as silicon or germanium. The substrate may include a patterned mask layer previously deposited and patterned on the substrate. For example, a mask layer may be deposited and patterned on a substrate including a blanket amorphous silicon layer. The layers on the substrate may also be patterned. Substrates may have “features” such as fins, or holes, which may be characterized by one or more of narrow and/or re-entrant openings, constrictions within the feature, and high aspect ratios. One example of a feature is a hole or via in a semiconductor substrate or a layer on the substrate. Another example is a trench in a substrate or layer. In various instances, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

The use of plasma during conventional etching presents numerous challenges and disadvantages. For instance, it is generally desirable to create the same plasma conditions for each ALE cycle of a single substrate as well as for all substrates in a batch, but it can be difficult to repeatedly recreate the same plasma conditions due to some plasmas changing due to accumulation of material in the process chamber. Additionally, many conventional ALE processes may cause damage to exposed components of the substrate, such as silicon oxide, may cause defects, and may increase the top-to-bottom ratio of a pattern and increase the pattern loading. Defects may lead to pattern-missing to the extent that the device may be rendered useless. Plasma-assisted ALE also utilizes small radicals, i.e., deeply dissociated radicals, that are more aggressive which causes them to remove more material than may be desired, thereby reducing the selectivity of this etching. As a result, conventional ALE techniques are often unsuitable for selectively etching some materials, such as aluminum dioxide, zirconium dioxide, hafnium dioxide, silicon nitride, and titanium nitride. It is therefore desirable to determine new etching techniques and apparatuses that do not use a plasma and that are able to provide rapid and precise temperature control of a substrate during processing.

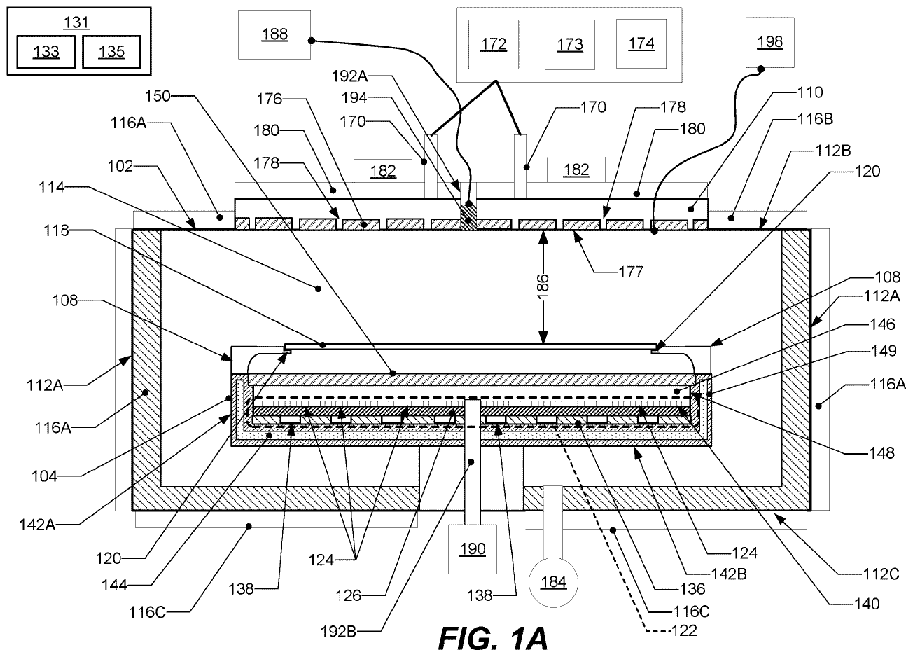

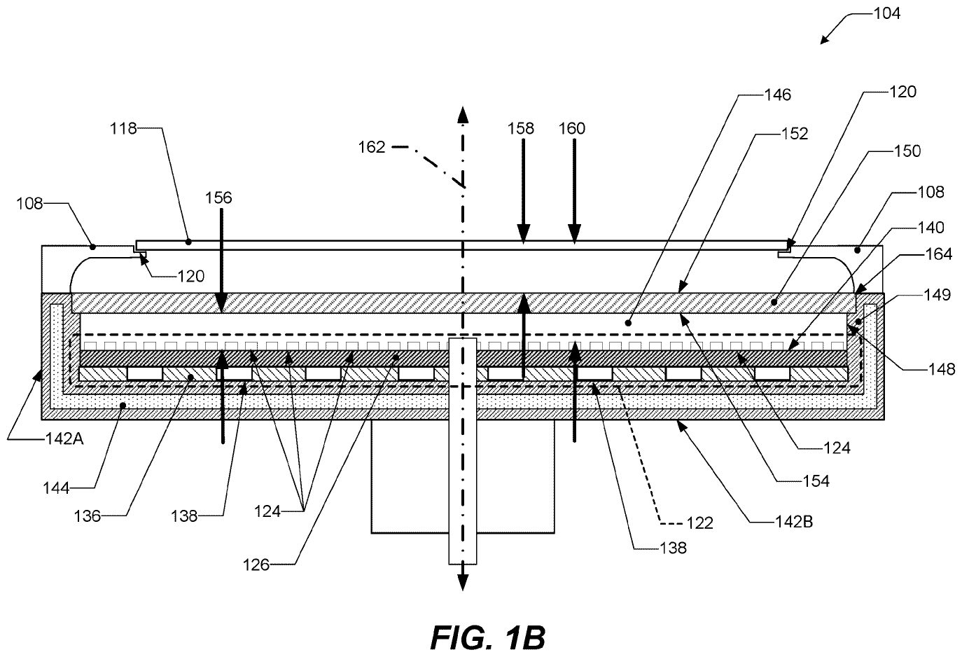

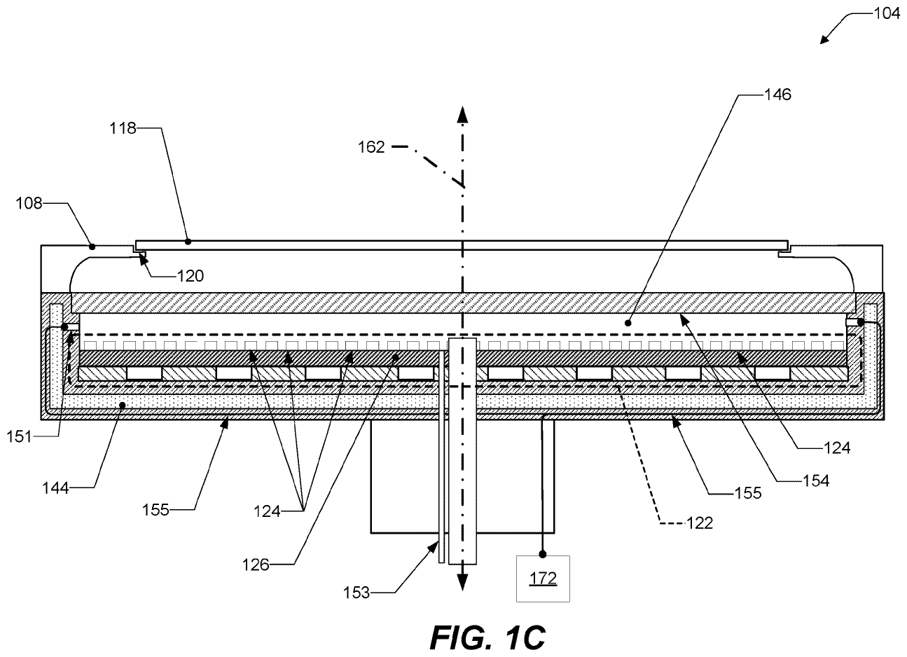

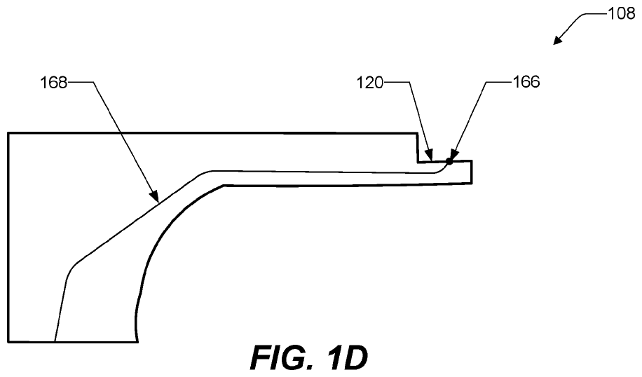

More generally, an apparatus may be designed or configured to provide variable reaction conditions over the course of an etch process, regardless of whether that process is an ALE process or some other etch process that employs varying conditions. In certain embodiments, the apparatus is designed or configured to provide rapidly varying temperature over the course of an etch process. Examples of such an apparatus are shown in and described below in connection with FIGS. 1A-1D.

Causing rapidly varying temperatures over the course of an etch process may require accurate temperature measurement during the process. In some cases, as will be discussed below in more detail, such temperature measurements are made of a wafer undergoing processing via an optical sensor. Such an optical sensor may measure changes in transparency of the wafer during processing. The changes in transparency may then be used to determine changes in temperature. In other words, relative temperatures (e.g., changes in temperature between two time points) may be determined. However, control of the etch process may be improved with knowledge of the absolute wafer temperature during processing. Accordingly, an initial wafer temperature measurement (e.g., prior to processing) may be useful in order to convert the relative temperature measurements obtained during processing to absolute temperature measurements.

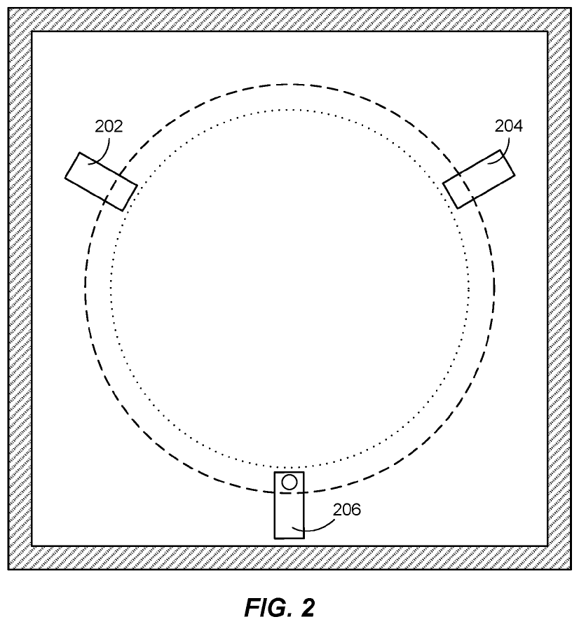

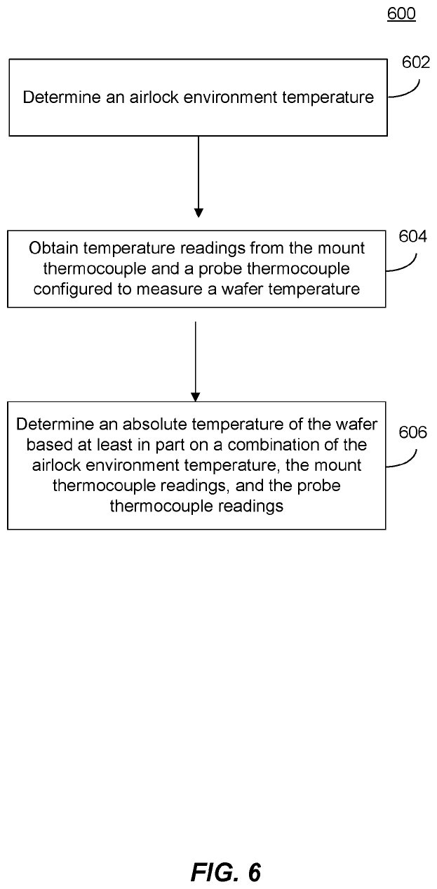

Disclosed herein are systems, methods, and techniques for determining an absolute wafer temperature measurement. The absolute wafer temperature measurement may be made prior to processing of the wafer and may be used to initialize or calibrate relative temperature measurements made in the process chamber during processing. The absolute wafer temperature measurement may be made in an airlock prior to transfer of the wafer to the process chamber. In some implementations, the absolute wafer temperature measurement may be made using a temperature probe integrated in a wafer support of the airlock, as shown in and described below in connection with FIGS. 2-5. In some embodiments, the wafer support may include two thermocouples, a first thermocouple configured to measure a temperature of the wafer resting proximate to a temperature probe, and a second thermocouple configured to measure an ambient temperature in a vicinity of the probe. The absolute wafer temperature may then be determined based on a combination of readings from the two thermocouples, thereby allowing for compensation of heat transfer within the airlock. Techniques for determining the absolute wafer temperature based on measurements from two thermocouples are shown in and described below in connection with FIG. 6.

### Apparatuses for Thermal Processing

Provided herein are methods and apparatuses for semiconductor processing, for example to etch a semiconductor substrate using thermal energy, rather than or in addition to plasma energy. In certain embodiments, etching that relies upon chemical reactions in conjunction with primarily thermal energy, not a plasma, to drive the chemical reactions may be considered “thermal etching”. In various embodiments, apparatuses described herein are designed or configured to rapidly heat and cool a substrate, and precisely control a substrate's temperature. In some embodiments, the substrate is rapidly heated and its temperature is precisely controlled using, in part, visible light emitted from light emitting diodes (LEDs) positioned in a pedestal under the substrate. The visible light may have wavelengths that include and range between 400 nanometers (nm) and 800 nm. The pedestal may include various features for enabling substrate temperature control, such as a transparent window that may have lensing for advantageously directing or focusing the emitted light, reflective material also for advantageously directing or focusing the emitted light, and temperature control elements that assist with temperature control of the LEDs, the pedestal, and the chamber.

The apparatuses may also thermally isolate, or thermally “float,” the substrate within the processing chamber so that only the smallest thermal mass is heated, the ideal smallest thermal mass being just the substrate itself, which enables faster heating and cooling. The substrate may be rapidly cooled using a cooling gas and radiative heat transfer to a heat sink, such as a top plate (or other gas distribution element) above the substrate, or both. In some instances, the apparatus also includes temperature control elements within the processing chamber walls, pedestal, and top plate (or other gas distribution element), to enable further temperature control of the substrate and processing conditions within the chamber, such the prevention of unwanted condensation of processing gases and vapors.

The apparatuses may also be configured to implement various control loops to precisely control the substrate and the chamber temperatures (e.g., with a controller configured to execute instructions that cause the apparatus to perform these loops). This may include the use of various sensors that determine substrate and chamber temperatures as part of open loops and feedback control loops. These sensors may include temperature sensors in the substrate supports which contact the substrate and measure its temperature, and non-contact sensors such as photodetectors to measure light output of the LEDs and a pyrometer configured to measure the temperature of different types of substrates. As described in more detail below, some pyrometers determine an item's temperature by emitting infrared or other optical signals at the item and measuring the signals reflected or emitted by the item. However, many silicon substrates cannot be measured by some pyrometers because the silicon can be optically transparent at various temperatures and with various treatments, e.g., doped or low doped silicon. For example, a low doped silicon substrate at a temperature less than 200° C. is transparent to infrared signals. The pyrometers provided herein are able to measure multiple types of silicon substrates at various temperatures.

FIG. 1A depicts a cross-sectional side view of an example apparatus in accordance with disclosed embodiments. As detailed below, this apparatus 100 is capable of rapidly and precisely controlling the temperature of a substrate, including performing thermal etching operations. The apparatus 100 includes a processing chamber 102, a pedestal 104 having a substrate heater 106 and a plurality of substrate supports 108 configured to support a substrate 118, and a gas distribution unit 110.

The processing chamber 102 includes sides walls 112A, a top 112B, and a bottom 112C, that at least partially define the chamber interior 114, which may be considered a plenum volume. As stated herein, it may be desirable in some embodiments to actively control the temperature of the processing chamber walls 112A, top 112B, and bottom 112C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 112A, the top 112B, and the bottom 112C. As illustrated in FIG. 1A, chamber heaters 116A are positioned on and configured to heat the chamber walls 112A, chamber heaters 116B are positioned on and configured to heat the top 112B, and chamber heaters 116C are positioned on and configured to heat the bottom 112C. The chamber heaters 116A-116C may be resistive heaters that are configured to generate heat when an electrical current is flowed through a resistive element. Chamber heaters 116A-116C may also be fluid conduits through which a heat transfer fluid may be flowed, such as a heating fluid which may include heated water. In some instances, the chamber heaters 116A-116C may be a combination of both heating fluid and resistive heaters. The chamber heaters 116A-116C are configured to generate heat in order to cause the interior surfaces of each of the chamber walls 112A, the top 112B, and the bottom 112C to the desired temperature, which may range between about 40° C. and about 150° C., including between about 80° C. and about 130° C., about 90° C. or about 120° C., for instance. It has been discovered that under some conditions, water and alcohol vapors do not condense on surfaces kept at about 90° C. or higher.

The chamber walls 112A, top 112B, and bottom 112C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anyhydrous HF, water vapor, methanol, isopropyl alcohol, chlorine, fluorine gases, nitrogen gas, hydrogen gas, helium gas, and mixtures thereof.

The apparatus 100 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 184 configured to pump the chamber interior 114 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr.

Various features of the pedestal 104 will now be discussed. The pedestal 104 includes a heater 122 (encompassed by the dashed rectangle in FIG. 1A) that has a plurality of LEDs 124 that are configured to emit visible light having wavelengths including and between 400 nm to 800 nm, including 450 nm. The heater LEDs emit this visible light onto the backside of the substrate which heats the substrate. Visible light having wavelengths from about 400 nm to 800 nm is able to quickly and efficiently heat silicon substrates from ambient temperature, e.g., about 20° C., to temperatures as high as about 600° C. because silicon absorbs visible light within this range. In contrast, radiant heating, including infrared radiant heating, may ineffectively heat silicon at temperatures up to about 400° C. because silicon tends to be transparent to infrared at temperatures lower than about 400° C. Additionally, radiant heaters that directly heat the topside of a substrate, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat some pedestals to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

FIG. 1B depicts the pedestal of FIG. 1A with additional features in accordance with various embodiments. As identified in FIG. 1B, the window 150 includes a top surface 152 that faces the substrate 118 supported by the pedestal 104, and a bottom surface 154 that faces the substrate heater 122. In some embodiments, the top and the bottom surfaces 152 and 154 may be flat, planar surfaces (or substantially flat, e.g., within ±10% or 5% of flat). In some other instances, the top 152, bottom 154, or both top 152 and bottom 154 may be nonplanar surfaces. The nonplanarity of these surfaces may be configured to refract and/or direct the light emitted by the substrate heater's 122 LEDs 124 to more efficiently and/or effectively heat the substrate. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 150 may have features that act as an array of lenses which are oriented to focus the light emitted by one or more LEDs, such as each LED.

With the window 150 positioned above the substrate heater 122, the window 150 gets heated by the substrate heater 122 which can affect the thermal environment around the substrate. Depending on the material or materials used for the window 150, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface 152 is 30° C. hotter than the bottom surface 154. It may therefore be advantageous to adjust and configure the chamber to account for and reduce the thermal effects of the window. This may include detecting the substrate's temperature and adjusting the substrate heater to account for the heat retained by the window.

This may also include various configurations of the pedestal, such as actively cooling the window. In some embodiments, like that shown in FIGS. 1A and 1B, the window 150 may be offset from the substrate heater 122 by a first distance 156. In some embodiments, this first distance may be between about 2 mm and 50 mm, including between about 5 mm and 40 mm. A cooling fluid, such as an inert gas, may be flowed between the window 150 and the substrate heater 122 in order to cool both the window 150 and the substrate heater 122. The pedestal may have one or more inlets and one or more outlets for flowing this gas within the plenum volume, or bowl 146, of the pedestal 104. The one or more inlets are fluidically connected to the inert gas source outside the processing chamber 102, which may include through fluid conduits that may be at least partially routed inside the pedestal 104. The one or more outlets are fluidically connected to an exhaust or other environment outside the processing chamber 102, which may also be through fluid conduits running within the pedestal. In FIG. 1C, which depicts the pedestal of FIG. 1B with additional features in accordance with various embodiments, one or more inlets 151 are positioned in the sidewalls 149 and extend through the internal surface 148; the one or more inlets are also fluidically connected to agas source 172 (e.g., an inert gas source) through, in part, fluid conduits 155 that are routed through the pedestal 104. A single outlet 153 is positioned in a center region, i.e., not in the exact center but in close proximity, of the substrate heater 122. In some embodiments, the one or more gas inlets and one or more outlets may be switched, such that the one or more outlets extend through the sidewalls 149 (i.e., they are items 151 in FIG. 1C), and the one or more inlets may be the center region of the substrate heater 122 (i.e., they are item 153 in FIG. 1C). In some embodiments, there may be more than one outlet; in some embodiments, there may only be a single gas inlet. In some embodiments, one or more gas inlets extend through the internal surface 148 of the pedestal sidewall 149 underneath the LED heater 122 and one or more gas outlets extend through another part of the pedestal sidewall 149, such as a mounting bracket between the LED heater 122 and the pedestal sidewall 149.

In some embodiments, the window may be placed in direct, thermal contact with the substrate heater and the pedestal cooler may be configured to cool both the PCB and the window. In some embodiments, as also shown in FIGS. 1A and 1B, the window 150 may be thermally connected to the sidewalls 149 of the pedestal 104 in order to transfer some of the retained heat in the window 150 to the pedestal 104. This transferred heat may be further transferred out of the pedestal using, for instance, the pedestal heater 144 which may flow fluid through the pedestal 104 that is heated to between about 20° C. and 100° C., for instance. This heated fluid may be cooler than the temperature of the pedestal 104 at the thermal connection with the window 150. In some embodiments, the window 150 may have one or more fluid conduits within the window 150 through which transparent cooling fluid may be configured to flow. The fluid may be routed to the window through the pedestal from a fluid source or reservoir outside the chamber.

As shown in FIGS. 1A and 1B, the pedestal's 104 substrate supports 108 are configured to support the substrate 118 above and offset from the window 150 and the substrate heater 122. In certain embodiments, the temperature of the substrate can be rapidly and precisely controlled by thermally floating, or thermally isolating, the substrate within the chamber. It is desirable to position the substrate so that the smallest thermal mass is heated and cooled. This thermal floating is configured to position the substrate so that it has minimal thermal contact (which includes direct and radiation) with other bodies in the chamber.

The pedestal 104 is therefore configured, in some embodiments, to support the substrate 118 by thermally floating, or thermally isolating, the substrate within the chamber interior 114. The pedestal's 104 plurality of substrate supports 108 are configured to support the substrate 118 such that the thermal mass of the substrate 118 is reduced as much as possible to the thermal mass of just the substrate 118. Each substrate support 108 may have a substrate support surface 120 that provides minimal contact with the substrate 118. The number of substrate supports 108 may range from at least 3 to, for example, at least 6 or more. The surface area of the support surfaces 120 may also be the minimum area required to adequately support the substrate during processing operations (e.g., in order to support the weight of the substrate and prevent inelastic deformation of the substrate).

The substrate supports are also configured to prevent the substrate from being in contact with other elements of the pedestal, including the pedestal's surfaces and features underneath the substrate. As seen in FIGS. 1A and 1B, the substrate supports 108 hold the substrate 118 above and offset from the next adjacent surface of the pedestal 104 below the substrate 118, which is the top surface 152 (identified in FIG. 1B) of the window 150. As can be seen in these Figures, a volume or gap exists underneath the substrate, except for the contact with the substrate supports. As illustrated in FIG. 1B, the substrate 118 is offset from the top surface 152 of the window 150 by a distance 158. This distance 158 may affect the thermal effects caused by the window 150 to the substrate 118. The larger the distance 158, the less the effects. It was found that a distance 158 of 2 mm or less resulted in a significant thermal coupling between the window and the substrate; it is therefore desirable to have a larger distance 158 than 2 mm, such as at least about 5 mm, about 10 mm, about 15 mm, about 20 mm, about 30 mm, about 50 mm, or about 100 mm, for example.

The substrate 118 is also offset from the substrate heater 122 (as measured in some instances from a top surface of the substrate heater 122 which may be the top surface of the LEDs 124) by a distance 160. This distance 160 affects numerous aspects of heating the substrate 118. In some embodiments, a distance 160 of between about 10 mm and 90 mm, between about 5 mm and 100 mm, including between about 10 mm and 30 mm, for instance, provides a substantially uniform heating pattern and acceptable heating efficiency.

As stated, the substrate supports 108 are configured to support the substrate 118 above the window. In some embodiments, these substrate supports are stationary and fixed in position; they are not lift pins or a support ring. In some embodiments, at least a part of each substrate support 108 that includes the support surface 120 may be comprised of a material that is transparent at least to light emitted by LEDS 124. This material may be, in some instances, quartz or sapphire. The transparency of these substrate supports 108 may enable the visible light emitted by the substrate heater's 122 LEDs to pass through the substrate support 108 and to the substrate 118 so that the substrate support 108 does not block this light and the substrate 118 can be heated in the areas where it is supported. This may provide a more uniform heating of the substrate 118 than with a substrate support comprising a material opaque to visible light. In some other embodiments, the substrate supports 108 may be comprised of a non-transparent material, such as zirconium dioxide (ZrO₂).

In some embodiments, such as those shown in FIG. 1B, the substrate supports 108 may be positioned closer to a center axis 162 of the window than the outer diameter 164 of the window 150. In some instances, portions of these substrate supports may extend over and above the window 150.

In some embodiments, the substrate supports may each contain a temperature sensor that is configured to detect the temperature of the substrate positioned on the support surface of the substrate supports. FIG. 1D depicts a substrate support of FIGS. 1A and 1B in accordance with disclosed embodiments. Here, the support surface 120 of the substrate support 108 is identified, along with a temperature sensor 166. In some embodiments, this temperature sensor 166 extends through the support surface 120 such that the temperature sensor 166 is in direct contact with a substrate held by the support surface 120. In some other embodiments, the temperature sensor 166 is positioned within the substrate support 108 and below the support surface 120. In some embodiments, this temperature sensor 166 is a thermocouple. In some other embodiments, the temperature sensor 166 may be a thermistor, a resistance temperature detector (RTD), and semiconductor sensor. The electrical wiring 168 for the temperature sensor 166 may be routed through the substrate support 108 and may also be routed through the pedestal 104.

Referring back to FIG. 1A, in some embodiments, the pedestal is also configured to move vertically. This may include moving the pedestal such that a gap 186 between a faceplate 176 of the gas distribution unit 110 and the substrate 118 is capable of being in a range between about 2 mm and 70 mm. Moving the pedestal vertically may enable active cooling of the substrate as well as rapid cycling time of processing operations, including flowing gas and purging, due to a low volume created between the gas distribution unit 110 and the substrate 118. This movement may also enable the creation of a small process volume between the substrate and the gas distribution unit which can result in a smaller purge and process volumes and thus reduce purge and gas movement times and increase throughput.

The gas distribution unit 110 is configured to flow process gases, which may include liquids and/or gases, such as a reactant, modifying molecules, converting molecules, or removal molecules, onto the substrate 118 in the chamber interior 114. As seen in FIG. 1A, the gas distribution unit 110 includes one or more fluid inlets 170 that are fluidically connected to one or more gas sources 172 and/or one or more vapor sources 174. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 110 also includes the faceplate 176 that includes a plurality of through-holes 178 that fluidically connect the gas distribution unit 110 with the chamber interior 114. These through-holes 178 are fluidically connected to the one or more fluid inlets 170 and also extend through a front surface 177 of the faceplate 176, with the front surface 177 configured to face the substrate 118. In some embodiments, the gas distribution unit 110 may be considered a top plate and in some other embodiments, it may be considered a showerhead.

The through-holes 178 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

Referring back to FIG. 1A, the gas distribution unit 110 may also include a unit heater 180 that is thermally connected to the faceplate 176 such that heat can be transferred between the faceplate 176 and the unit heater 180. The unit heater 180 may include fluid conduits in which a heat transfer fluid may be flowed. Similar to above, the heat transfer fluid may be heated to a temperature range of about 20° C. and 120° C., for example. In some instances, the unit heater 180 may be used to heat the gas distribution unit 110 to prevent unwanted condensation of vapors and gases; in some such instances, this temperature may be at least about 90° C. or 120° C.

In some embodiments, the gas distribution unit 110 may include a second unit heater 182 that is configured to heat the faceplate 176. This second unit heater 182 may include one or more resistive heating elements, fluid conduits for flowing a heating fluid, or both. Using two unit heaters 180 and 182 in the gas distribution unit 110 may enable various heat transfers within the gas distribution unit 110. This may include using the first and/or second unit heaters 180 and 182 to heat the faceplate 176 in order to provide a temperature-controlled chamber, as described above, in order to reduce or prevent unwanted condensation on elements of the gas distribution unit 110.

The apparatus 100 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 180 that flows the heat transfer fluid through fluid conduits may be used to cool the substrate 118 by transferring heat away from the faceplate 176 that is transferred from the substrate 118. A substrate 118 may therefore be cooled by positioning it in close proximity to the faceplate 176, such as by a gap 186 of less than or equal to 5 mm or 2 mm, such that the heat in the substrate 118 is radiatively transferred to the faceplate 176, and transferred away from the faceplate 176 by the heat transfer fluid in the first unit heater 180. The faceplate 176 may therefore be considered a heat sink for the substrate 118 in order to cool the substrate 118.

In some embodiments, the apparatus 100 may further include a cooling fluid source 173, which may contain a cooling fluid (a gas or a liquid), and a cooler (not pictured) configured to cool the cooling fluid to a desired temperature, such as less than or equal to about 90° C., less than or equal to about 70° C., less than or equal to about 50° C., less than or equal to about 20° C., less than or equal to about 10° C., less than or equal to about 0° C. less than or equal to about −50° C., less than or equal to about −100° C., less than or equal to about −150° C., less than or equal to about −190° C., about −200° C., or less than or equal to about −250° C., for instance. The apparatus 100 includes piping to deliver the cooling fluid to the one or more fluid inlets 170, and the gas distribution unit 110 which is configured to flow the cooling fluid onto the substrate. In some embodiments, the fluid may be in liquid state when it is flowed to the processing chamber 102 and may turn to a vapor state when it reaches the chamber interior 114, for example if the chamber interior 114 is at a low pressure state, such as described above, e.g., between about 0.1 Torr and 10 Torr, or between about 0.1 Torr and 100 Torr, or between about 20 Torr and 200 Torr, for instance. The cooling fluid may be an inert element, such as nitrogen, argon, or helium. In some instances, the cooling fluid may include, or may only have, a non-inert element or mixture, such as hydrogen gas. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 100 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

In some embodiments, the apparatus 100 may include a mixing plenum for blending and/or conditioning process gases for delivery before reaching the fluid inlets 170. One or more mixing plenum inlet valves may control introduction of process gases to the mixing plenum. In some other embodiments, the gas distribution unit 110 may include one or more mixing plenums within the gas distribution unit 110. The gas distribution unit 110 may also include one or more annular flow paths fluidically connected to the through-holes 178 which may equally distribute the received fluid to the through-holes 178 in order to provide uniform flow onto the substrate.

The apparatus 100 may also include one or more additional non-contact sensors for detecting the temperature of the substrate. Such sensors may include improved pyrometers, for instance. Although conventional pyrometers are not able to detect certain substrates within particular temperature ranges, the pyrometer described herein overcomes these problems. For instance, the pyrometer is configured to detect multiple emission ranges in order to detect multiple types of substrates, e.g., doped, low doped, or not doped, at various temperature ranges. This includes a configuration to detect emission ranges of about 0.95 microns to about 1.1 microns, about 1 micron, about 1 to about 4 microns, and/or about 8 to 15 microns. The pyrometer is also configured to detect the temperature of a substrate at a shorter wavelength in order to differentiate the signal from the thermal noise of the chamber.

The pyrometer may include an emitter configured to emit infrared signals and a detector configured to receive emissions. Referring to FIG. 1A, the apparatus includes the pyrometer 188 having an emitter within the pyrometer 188 and a detector 190. The pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 192A on the top of the processing chamber 102, such as the port 192A through the center of the gas distribution unit 110, and a second port 192B through the pedestal 104 and substrate heater 122. The emitter in the pyrometer 188 may be connected to one of the ports 192A or 192B via a fiberoptic connection, such as the first port 192A as shown in FIG. 1A, and the detector is optically connected to the other port, such as the second port 192B in FIG. 1A. The first port 192A may include a port window 194 to seal the first port 192A from the chemistries within the chamber interior 114. The second port 192B is seen in FIG. 1A extending through the pedestal 104 and the substrate heater such that the emitter's emissions can pass through the substrate, through the window 150, into the second port 192B and to the detector 190 that may be positioned in the second port or optically connected to the second port through another fiberoptic connection (not shown). In some other embodiments, the emitter and the detector are flipped, such that the emitter emits through the second port 192B and the detector detects through the first port 192A.

The apparatus 100 may also include one or more optical sensors 198 to detect one or more metrics of the visible light emitted by the LEDs. In some embodiments, these optical sensors may be one or more photodetectors configured to detect the light and/or light intensity of the light emitted by the LEDs of the substrate heater. In FIG. 1A, a single optical sensor 198 is shown as connected to the chamber interior 114 via fiberoptic connection such that the optical sensor 198 is able to detect light emitted by the substrate heater 122. The optical sensor 198, and additional optical sensors, can be positioned in various locations in the top and sides, for instance, of the processing chamber 102 in order to detect the emitted light at various locations within the processing chamber 102. As discussed below, this may enable the measurement and adjustment of the substrate heater, such as the adjustment of one or more independently controllable zones of the LEDs. In some embodiments, there may be a plurality of optical sensors 198 arranged along a circle or multiple concentric circles in order to measure various regions of the LEDs throughout the processing chamber 102. In some embodiments, the optical sensors may be positioned inside the chamber interior 114.

In some embodiments, the apparatuses described herein may include a controller that is configured to control various aspects of the apparatus in order to perform the techniques described herein. For example, referring back to FIG. 1A, apparatus 100 includes a controller 131 (which may include one or more physical or logical controllers) that is communicatively connected with and that controls some or all of the operations of a processing chamber. The system controller 131 may include one or more memory devices 133 and one or more processors 135. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

### Systems for Incoming Wafer Temperature Measurement

As described above, in situ temperature measurements of a wafer undergoing processing may be crucial for performing a given fabrication process, for example, to accurately control wafer heating within a process chamber. In some cases, a process chamber may include a temperature sensor that measures temperature changes of the wafer during processing. The temperature changes may be relative changes, e.g., a change in temperature of the wafer from a first time point to a second time point, rather than an absolute temperature. In some embodiments, the temperature sensor may measure temperature using optical measurements that measure a transparency of the wafer. However, in cases in which such a temperature sensor makes relative measurements, obtaining an accurate initial measurement of the wafer, prior to the wafer undergoing processing, may be important to accurately initialize and/or calibrate subsequent relative temperature measurements during processing.

Disclosed herein are systems, techniques, and methods for obtaining an absolute wafer temperature measurement. As described herein, an initial absolute temperature measurement may be made while a wafer is in an airlock (e.g., prior to being transferred to a process chamber). Obtaining an initial absolute temperature measurement while in the airlock may be preferable to obtaining such a temperature measurement while the wafer is in the process chamber for multiple reasons. For example, circuitry (e.g., thermocouples and/or thermocouple wires) used to measure an absolute temperature may not be suited for the chemistries (e.g., hydrofluoric (HF) acid) that may be present in the process chamber, and may therefore negatively impact the temperature measurement circuitry. As another example, obtaining absolute temperature measurements while in the process chamber may use up valuable resource time associated with the process chamber by performing measurements within the process chamber that need not be performed in the process chamber.

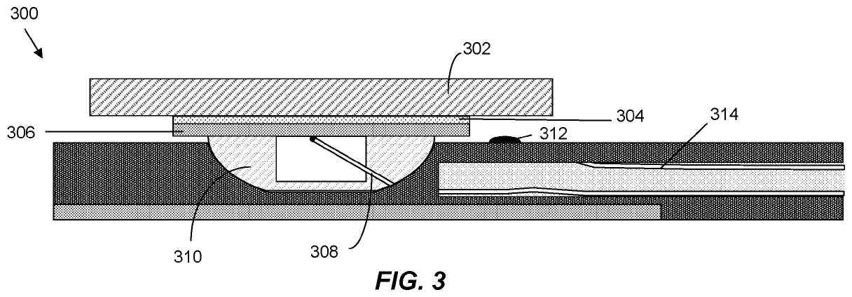

As described herein, a temperature probe configured to measure an absolute temperature of a wafer may be integrated into a wafer support. In some embodiments, the wafer support may be a wafer support of an airlock. It should be understood that, although the temperature probe described herein generally relates to measuring a wafer temperature while the wafer is in an airlock, the temperature probe may be integrated into any suitable wafer support associated with any component or location of a process chamber .. FIG. 2 illustrates an example airlock with wafer supports. The temperature probe may be configured to obtain a temperature of the wafer through heat transfer. For example, a portion of the temperature probe proximate to a backside of the wafer (e.g., that rests on the wafer support) may be made of a thermally conductive material, such as Aluminum Nitride (AIN), a super silicon carbide, and/or any other suitable material having high thermal conductivity. In other words, the temperature probe may be configured to rest proximate to the wafer without touching the backside of the wafer. In some implementations, the temperature probe may be configured to be within about 1 micron, 10 microns, 100 microns, etc. of the backside of the wafer. Heat may conduct through the probe to a thermocouple configured to measure the temperature of the backside of the wafer. FIGS. 3-5 illustrate various views of an example wafer support with an integrated temperature probe, as will be described below in more detail. It should be noted that the temperature probe described herein may be used to accurately obtain a wafer temperature without utilizing backside gas injection. This in contrast to temperature measurements that may be implemented using an ESC, which rely on backside gas injection.

In some implementations, the initial absolute temperature measurement may be utilized by a controller to initialize and/or calibrate relative temperature measurements of the wafer obtained when the wafer is in the process chamber. In other words, in some embodiments, the initial absolute temperature measurement of the wafer obtained while the wafer is in the airlock may be utilized to transform relative temperature measurements of the wafer obtained in the process chamber to absolute temperature measurements, which may subsequently be utilized to control wafer processing.

In some embodiments, a temperature probe may include two thermocouples. As described above (and as shown in and described below in connection with FIGS. 3-5), a first thermocouple may measure the temperature of the backside of the wafer. A second thermocouple may be integrated on a portion of the temperature probe farther from the wafer than the first thermocouple. For example, the second thermocouple may be integrated toward an arm of the wafer support. The second thermocouple may serve to obtain an absolute temperature of the ambient region of the wafer (e.g., in the area of the wafer support). The temperature obtained by the second thermocouple may serve to compensate or calibrate the wafer temperature obtained using the first thermocouple. For example, the temperature obtained by the second thermocouple, representing the ambient temperature near the wafer, may be used to compensate for a changing environment of the airlock which may affect heat transfer between the wafer and the first thermocouple.

FIG. 2 is a top view of an example airlock in accordance with some embodiments. As illustrated, an airlock may include one or more wafer supports, such as a first wafer support 202, a second wafer support 204, and a third wafer support 206. In instances in which multiple wafer supports are utilized in an airlock, one or more of the wafer supports may include an integrated temperature probe. In the example shown in FIG. 2, third wafer support 206 includes an integrated wafer support, whereas first wafer support 202 and second wafer support 204 do not include integrated temperature probes. It should be understood that an airlock may include any number of wafer supports (e.g., one, two, three, or the like), and any subset (including all) of the wafer supports may include integrated temperature probes.

In some embodiments, a temperature probe integrated into a wafer support may include two thermally conductive pads which transfer heat from a wafer to a thermocouple. A first side of a first conductive pad may be configured to be proximate to a backside of a wafer. The first side of the second conductive pad may be adhered to a second side of the second conductive pad. For example, the two conductive pads may be adhered using a thermal gasket adhesive, epoxy, or the like.

In some implementations, a first conductive pad configured to be proximate to the backside of the wafer may be any highly thermally conductive material, such as AlN, a silicon carbide, or the like. In some implementations, the thickness of the first conductive pad may be less than about 0.05 inches. For example, in some embodiments, the thickness of the first conductive pad may be within a range of about 0.015 inches-0.035 inches. It should be noted that, as used herein, “about” may refer to a value within +/−1%, +/−5%, or the like, of a given value or range.

In some implementations, a second conductive pad configured to be adhered to the first conductive pad and configured to be operatively coupled to a thermocouple wire may be made of any suitable thermally conductive material. For example, in some implementations, the second conductive pad may comprise Nickel (Ni). As another example, in some implementations, the second conductive pad may comprise Aluminum (Al). In some embodiments, the second conductive pad may be made of a material that is thermally conductive and relatively inert to prevent oxidation, corrosion, etc. In some implementations, the second conductive pad may have a thickness that is less than a thickness of the first conductive pad that is configured to be proximate to the wafer. For example, in some implementations, the second conductive pad may have a thickness that is roughly an order of magnitude less than the thickness of the first conductive pad. In some implementations, the second conductive pad may have a thickness of less than about 0.007 inches. For example, in some embodiments, the second conductive pad may have a thickness within a range of about 0.002 inches-0.006 inches.

In some implementations, the first conductive pad configured to be proximate to the backside of the wafer may be adhered to the second conductive pad configured to be operatively coupled to a thermocouple wire. The adhesive may be a thermal gasket adhesive, thermal epoxy, or the like. The adhesive may have a thickness that is about the thickness of the second conductive pad. In some implementations, a thickness of the adhesive may be less than about 0.005 inches. For example, in some embodiments, the thickness of the adhesive may be within a range of about 0.001 inches-0.003 inches. It should be noted that, in some implementations, the first conductive pad may be directly bonded to the second conductive pad with no intermediate adhesive.

In some implementations, the temperature probe may be configured to pivot or rotate about a gimbal within a socket of the wafer holder in which the temperature probe is disposed. For example, a second conductive pad to which the thermocouple wire is operatively coupled may be attached to or connected to a ball of a ball and socket joint. In some implementations, the ball and socket joint may be configured to allow the temperature probe to pivot or rotate about to have a tilt within +/−2 degrees of a neutral position. Allowing the temperature probe to pivot or rotate about the gimbal may allow for temperature measurements of wafers with backsides that are not perfectly flat (e.g., due to wafer bow). In other words, the temperature probe may pivot in accordance with the wafer bow to allow for better proximate contact with the backside of the wafer.

FIG. 3 shows a cross-sectional side view schematic diagram of an example wafer support 300 with an integrated temperature probe. As illustrated, a first conductive pad 302 is configured to be proximate to a backside of a wafer (not shown). First conductive pad 302 may be made of AlN, a silicon carbide, or another highly thermally conductive material. First conductive pad 302 is adhered to second conductive pad 306 via an adhesive 304. Second conductive pad 306 may be made of Ni, Al, or another thermally conductive material. Adhesive 304 may be a thermal gasket, a thermal adhesive, or the like. As illustrated, a thermocouple wire 308 is operatively connected to a bottom side of second conductive pad 306. Thermocouple wire 308 may be welded to the bottom side of second conductive pad 306. Thermocouple wire 308 may then pass through a body of wafer support 300, and eventually feed through to, e.g., read-out circuitry (not shown).

Wafer support 300 additionally includes a second thermocouple that includes thermocouple end 312 and second thermocouple wire 314. As described above, the second thermocouple may be used to determine an absolute temperature in the environment in which the wafer resides, whereas the first thermocouple may be used to determine an absolute temperature of the wafer itself.

The temperature probe (which includes first conductive pad 302, adhesive 304, second conductive pad 306, and at least a portion of first thermocouple wire 308) is configured to pivot about a gimbal. For example, as illustrated in FIG. 3, the bottom side of second conductive pad 306 is connected to ball 310 of a ball and socket joint, which allows the temperature probe to pivot.

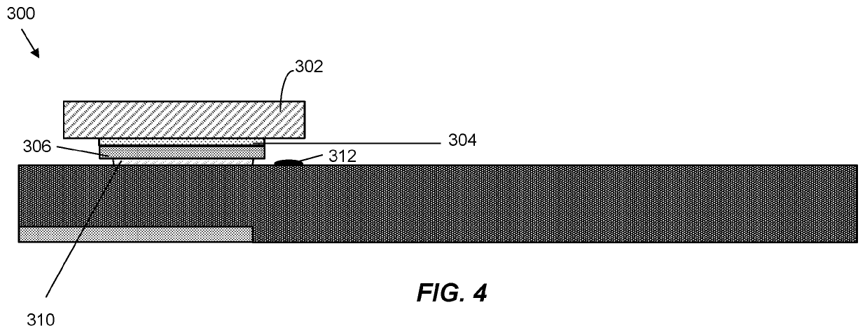

FIG. 4 illustrates a non-cross-sectional side view of the wafer support shown in and described above in connection with FIG. 3. As illustrated, the first thermocouple wire 308 and second thermocouple wire 314 are disposed within the body of wafer support 300, and are thus not shown in FIG. 4. Similarly, only a portion of ball 310 of the ball and socket joint protrudes above a top surface of wafer support 300, with a remaining portion residing within the body of wafer support 300.

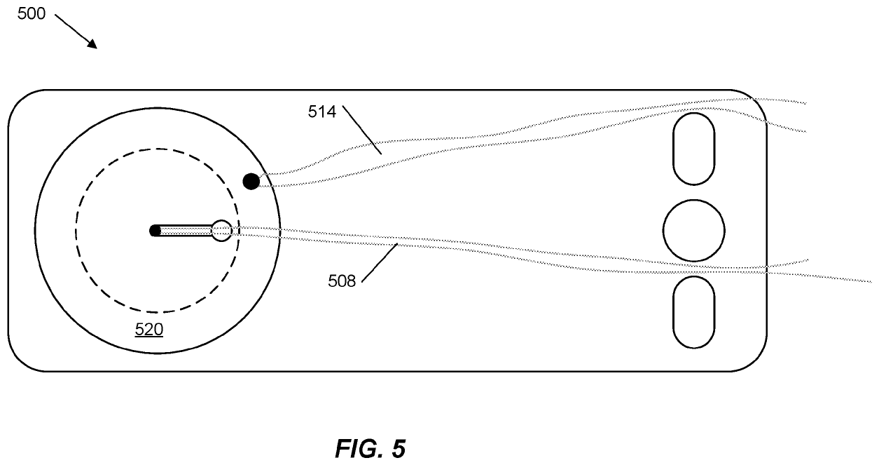

FIG. 5 illustrates a top view of an example wafer support 500 with an integrated temperature probe. FIG. 5 illustrates a first thermocouple wire 508 associated with a first thermocouple configured to obtain an absolute measurement of a wafer (e.g., residing proximate to the first conductive pad 302 of FIG. 3). FIG. 5 additionally illustrates a second thermocouple wire 514 associated with a second thermocouple configured to obtain an absolute measurement in a region associated with the wafer support (e.g., at some distance from the wafer).

Note that, as illustrated in FIG. 5, thermocouple wires may have some slack, which may allow for the temperature probe to pivot, as shown in and described above in connection with FIG. 3. Additionally, it should be noted that thermocouple wires may have any suitable thickness. For example, in some implementations, a thermocouple wire may have a thickness of less than about 0.01 inch, less than about 0.05 inches, or the like. The thermocouple wire may be sheathed in an insulator (e.g., Magnesium Oxide (MgO), or the like). The thickness of the insulator may be less than about 1.5 millimeters, less than about 1.0 millimeters, less than about 0.75 millimeters, or the like.

In some implementations, an absolute wafer temperature may be determined based on a combination of temperature readings or measurements from two thermocouples. The first thermocouple may be configured to be proximate to a backside of a wafer resting on a wafer support, and accordingly, to measure a temperature of the wafer. This temperature is sometimes referred to herein as the probe temperature, or T_{probe}. The second thermocouple may be configured to be further from the wafer relative to the first thermocouple. For example, the second thermocouple may be a mount thermocouple disposed in a region of the wafer support proximate to where the temperature probe is disposed. This temperature is sometimes referred to herein as the mount temperature, or Tₘₒᵤₙₜ.

In some implementations, the absolute wafer temperature may be based on a physical model (e.g., a linear combination) of the probe temperature and the mount temperature. In some implementations, the physical model may take into account a temperature of the airlock during an idle state. For example, in some implementations, the absolute wafer temperature may be determined based at least in part on a difference between the probe temperature and a temperature in the airlock during an idle state (e.g., prior to a wafer being transferred to the airlock) and/or a difference between the mount temperature and the temperature in the airlock during the idle state. In some embodiments, coefficients associated with the physical model (e.g., a linear combination and/or a weighted sum) may be determined using a calibration procedure. In some implementations, the calibration procedure may be performed prior to use of the apparatus. The calibration may involve heating up a temperature-metrology wafer, and measuring the temperature of the temperature-metrology wafer over time to determine parameters (e.g., coefficients) of the physical model.

FIG. 6 is a flowchart of an example process 600 for determining a temperature of a wafer in accordance with some embodiments. In some implementations, blocks of process 600 may be implemented by a processor or a controller, such as a controller of a semiconductor fabrication apparatus. In some embodiments, blocks of process 600 may be executed in an order other than what is shown in FIG. 6. In some implementations, two or more blocks of process 600 may be executed substantially in parallel. In some implementations, one or more blocks of process 600 may be omitted.

Process 600 can begin at 602 by determining an airlock environment temperature. In some implementations, the airlock environment temperature may be obtained using a thermocouple, such as a thermocouple as shown in and described above in connection with FIG. 3 (e.g., second thermocouple end 312 and second thermocouple wire 314) and 5 (e.g., second thermocouple wire 514). As described above, the airlock environment temperature (e.g., T_{Airlock}) may be determined by obtaining one or more readings during an idle state of the airlock (e.g., prior to a wafer being transferred to the airlock).

At 604, process 600 can obtain temperature readings from the mount thermocouple and a probe thermocouple. As described above in connection with FIGS. 3 and 5, the probe thermocouple is operatively connected to a thermally conductive pad proximate to a backside of a wafer. Accordingly, the probe thermocouple readings may represent a temperature of the wafer. In some embodiments, multiple temperature readings from a given thermocouple may be averaged together. For example, a series of mount thermocouple readings may be averaged together to generate a mount temperature (e.g., Tₘₒᵤₙₜ). As another example, a series of probe thermocouple readings may be averaged together to generate a probe temperature (e.g., T_{probe}).

At 606, process 600 can determine an absolute temperature of the wafer based at least in part on a combination of the airlock environment temperature (e.g., obtained at 602), the mount thermocouple readings (e.g., obtained at 604), and the probe thermocouple readings (e.g., obtained at 604). In some implementations, the absolute wafer temperature may be determined based at least in part on a difference between the probe temperature and a temperature in the airlock during an idle state (e.g., prior to a wafer being transferred to the airlock) and/or a difference between the mount temperature and the temperature in the airlock during the idle state.

### Controller

In some embodiments, the apparatuses described herein may include a controller that is configured to control various aspects of the apparatus in order to perform the techniques described herein. For example, referring back to FIG. 1A, apparatus 100 includes a controller 131 (which may include one or more physical or logical controllers) that is communicatively connected with and that controls some or all of the operations of a processing chamber. The system controller 131 may include one or more memory devices 133 and one or more processors 135. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, the controller 131 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 966, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 131 may be defined as electronics having various integrated circuits, logic, memory, and/or software that receive instructions, issue instructions, control operation, enable cleaning operations, enable endpoint measurements, and the like.

The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 131, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 131 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 131 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 131 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. This may include causing a substrate transfer robot to position the substrate in the chamber on the plurality of substrate supports causing power to be delivered to the LEDs so that they emit the visible light having wavelengths between 400 nm and 800 nm to heat the substrate to a first temperature, such as between 100° C. and 600° C., and causing etchant gases to flow into the chamber and etch the substrate. This may also include cooling, while the substrate is supported by only the plurality of substrate supports, the substrate by flowing the cooling gas onto the substrate, and/or moving the pedestal vertically so that the substrate is offset from a faceplate of a gas distribution unit by a first nonzero distance, and thereby causing heat to transfer from the substrate to the faceplate through noncontact radiation.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure. For the avoidance of any doubt, it is also to be understood that the above disclosure is at least directed to the following numbered implementations, as well as to other implementations that are evident from the above disclosure.

1. An apparatus for measuring wafer temperature, the apparatus comprising:
a first thermocouple disposed in or on a wafer support;
a first conductive pad with a first side and a second side; and
a second conductive pad with a first side and a second side, wherein:
the first thermocouple is operatively connected to the second side of the second conductive pad,
the second side of the first conductive pad is adhered to the first side of the second conductive pad,
the first side of the first conductive pad is configured to be proximate to a wafer, and
the first thermocouple is configured to indicate an absolute temperature of the wafer.

2. The apparatus of claim 1, further comprising a second thermocouple.

3. The apparatus of claim 2, wherein the second thermocouple is disposed such that an end of the second thermocouple is configured to be further from the wafer than an end of the first thermocouple, and wherein the second thermocouple is disposed in or on the wafer support.

4. The apparatus of claim 1, further comprising a ball and socket joint, wherein the second side of the second conductive pad is in contact with a ball of the ball and socket joint.

5. The apparatus of claim 4, wherein the second conductive pad is configured to tilt up to about +/−2 degrees.

6. The apparatus of claim 1, wherein the second conductive pad is comprised of nickel.

7. The apparatus of claim 1, wherein the second conductive pad has a thickness within a range of about 0.002 inches to 0.006 inches.

8. The apparatus of claim 1, wherein the first conductive pad comprises aluminum nitride.

9. The apparatus of claim 1, wherein the first conductive pad has a thickness of about 0.05 inches or less.

10. The apparatus of claim 1, wherein a wire of the first thermocouple is welded to the second side of the second conductive pad.

11. The apparatus of claim 1, wherein the second side of the first conductive pad is adhered to the first side of the second conductive pad by a thermal gasket adhesive.

12. The apparatus of claim 11, wherein the thermal gasket adhesive is about 0.0025 inches thick or less.

13. The apparatus of claim 1, wherein the absolute temperature of the wafer is provided without backside gas injection.

14. An apparatus for semiconductor processing, the apparatus comprising:
an airlock; and
a temperature probe, wherein:
the temperature probe is integrated into a wafer support located within the airlock,
the wafer support is configured to support a wafer, and
the temperature probe is configured to provide an absolute temperature of the wafer.

15. The apparatus of claim 14, further comprising a controller configured to utilize the absolute temperature in connection with readings from one or more other temperature probes disposed in a process station of the apparatus.

16. The apparatus of claim 14, wherein the
temperature probe further comprises:
a first thermocouple;
a first conductive pad with a first side and a second side; and
a second conductive pad with a first side and a second side, wherein:
the first thermocouple is operatively connected to the second side of the second conductive pad, and
the second side of the first conductive pad is adhered to the first side of the second conductive pad.

17. A method of determining wafer temperatures, the method comprising:
determining an environmental temperature of an airlock using a first thermocouple disposed in a wafer support during an idle state of the airlock;
obtaining temperature readings from the first thermocouple and a second thermocouple, wherein the second thermocouple is configured to measure a wafer temperature of a wafer proximate to a conductive pad operatively connected to the second thermocouple; and
determining an absolute temperature of the wafer based at least in part on a combination of the environmental temperature of the airlock, the temperature readings from the first thermocouple, and the temperature readings from the second thermocouple.

18. The method of claim 17, wherein the combination comprises a combination of: i) a difference between the temperature readings from the first thermocouple and the environmental temperature of the airlock; and ii) a difference between the temperature readings from the second thermocouple and the environmental temperature of the airlock.

19. The method of claim 18, wherein the combination of i) and ii) is a weighted sum using weights determined during a calibration procedure.
